(19) United States
(12) Patent Application Publication
(10) Pub. No.: US 2006/0094140 A1
(43) Pub. Date: May 4, 2006

(54) Manufacturing method for semiconductor light emitting device

(75) Inventors: Yukari Inoguchi, Nara-ken (JP); Hiroshi Umeda, Nara-ken (JP); Takahisa Kurahashi, Nara-ken (JP); Nobuyuki Watanabe, Nara-shi (JP); Tetsuroh Murakami, Tenri-shi (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka (JP)

(21) Appl. No.: 11/261,557

(22) Filed: Oct. 31, 2005

(30) Foreign Application Priority Data
Oct. 29, 2004 (JP) P2004-317054
Aug. 16, 2005 (JP) P2005-235973

(51) Int. Cl. H01L 21/00; H01L 21/30

(52) U.S. Cl. 438/22; 438/33; 438/28; 438/26; 438/455

(57) ABSTRACT

A manufacturing method for a semiconductor light emitting device is provided. The method includes preparing a first wafer in which at least one semiconductor layer including the emitter layer is formed; disposing a second wafer transparent to an emission wavelength of the emitter layer on the surface of the first wafer; providing a bonding failure prevention structure to at least either the first wafer or the second wafer for preventing bonding failures of the first wafer and the second wafer; and applying compressive force to a contact face between the first wafer and the second wafer while at the same time, heating the contact face. The first and second wafers can be bonded across their entire surfaces without causing bonding failure.

### CROSS-REFERENCE TO RELATED APPLICATION

This nonprovisional application claims priority under 35 U.S.C. §119(a) on Patent Applications No. 2004-317054 filed in Japan on Oct. 29, 2004, and No. 2005-235973 filed in Japan on Aug. 16, 2005, the entire contents of which are hereby incorporated by reference.

### BACKGROUND OF THE INVENTION

The present invention relates to a manufacturing method for a semiconductor light emitting device for use as a light source of, for examples, lighting systems, information displays and information transmission equipments.

Conventionally, it is very important to enhance the efficiency of extraction of light generated inside a light emitting diode (hereinbelow referred to as LED), i.e., external emission efficiency.

In order to enhance the external emission efficiency, LEDs usually use substrates transparent to emission wavelengths. If substrates opaque to emission wavelengths are used, emitted light is absorbed by the substrate, and therefore in terms of an emitter layer, light is substantially emitted only from a face opposed to the substrate (hereinbelow referred to as an upper face). If the substrates transparent to the emission wavelengths are used, light can be emitted not only from the upper face but from other faces. Moreover, in the case where the substrate-side face (hereinbelow referred to as a lower face) of the LED is bonded, light traveling from the emitter layer to the substrate side can be reflected by the lower face and can be emitted from the upper face and lateral faces. The LEDs having such transparent substrates have conventionally been applied to infrared LEDs using InGaAsP-based semiconductor materials, infrared and red LEDs using AlGaAs-based semiconductor materials, yellow LEDs using GaAsP-based semiconductor materials and green LEDs using GaP-based semiconductor materials.

In recent years, in development of red, yellow and green LEDs using AlGaInP-based semiconductor materials and the like, a wafer bonding technology for directly boding a plurality of substrates are rapidly coming into practical use. Enhancement of the external emission efficiency of LEDs is achieved by bonding the substrate transparent to emission wavelengths to an LED substrate with the wafer bonding technology.

Proposed as a first background art of this kind is a technology for directly bonding a GaP (gallium phosphide) transparent substrate onto the face of an AlGaInP-based (aluminum gallium indium phosphide) semiconductor layer formed on a GaAs (gallium arsenide) substrate through pressurization and high-temperature processing (see, e.g., Japan Patent No. 3230638).

Proposed as a second background art is a technology for wafer-bonding an LED emitter layer and a transparent layer via a bonding layer containing In (indium) (see, e.g., Japan Patent No. 3532953).

Proposed as a third background art is a technology in which a second epitaxial layer is grown via a mask on a first epitaxial layer grown on a first substrate, a trench extending to the mask is formed in the second epitaxial layer, and then a second substrate is wafer-bonded onto the second epitaxial layer so as to etch the mask via the trench, by which the second epitaxial layer and the second substrate are removed from the first substrate and the first epitaxial layer (see, e.g., JP 2001-53056 A).

Proposed as a fourth background art is a technology in which an epitaxial wafer having a layered product formed as an emitter layer on a GaAs substrate is formed, the epitaxial wafer is blade-diced in lengthwise and widthwise direction at 300 μm intervals to provide grooves having a width of 100 μm and a depth of 20 μm, and after a GaP substrate is bonded to the face of the epitaxial wafer having the grooves, the GaAs substrate of the epitaxial wafer is removed, electrodes are formed, and device isolation is performed to form LED chips (see, e.g., JP 2001-57441 A).

However, the respective background arts have the following problems.

That is, the first background art has a problem that with the wafers of 2 inches or 3 inches in diameter generally used in manufacturing of LEDs, it is difficult to bond the entire face of its transparent substrate uniformly with a high yield.

In a test conducted by an applicant of the present invention, with use of a jig 50 as shown in a front view in FIG. 7 and a plane view in FIG. 8, a second wafer 123 that was a GaP transparent substrate was pressurized in the state of being in close contact with the surface of a first wafer 122 which was composed of an AlGaInP-based semiconductor layer formed on a GaAs substrate, and high temperature processing was performed on these wafers in a heating furnace. The first and second wafers 122, 123 were wafers having a diameter of 2 inches. As a result, when the wafers were taken out from the heating furnace after execution of the high temperature processing, the wafers had cracks and it was impossible to proceed to the next step. In the case where the wafer was divided into four sections and bonded, a relatively large area was suffered from bonding failures attributed to the nonflatness of the bonding faces of the semiconductor layer and the transparent substrate. FIG. 9 shows the first wafer 122 before bonding, while FIG. 10 shows the first and second wafers 122, 123 after bonding. As shown in FIG. 10, the first and second wafers 122, 123 had cracks, and island-shaped bonded portions 110 were generated in the center of the wafer and on its external radial side, which disturbed bonding in other portions and thereby caused bonding failure. Thus, the first background art has a difficulty in application to mass production of LEDs.

In the second background art, as disclosed in first example, after an LED layer is formed on a growth substrate, the growth substrate is removed before a transparent substrate is wafer-bonded. An LED layer in the state that the growth substrate has been removed is thin and fragile, which causes a problem of a decreased yield. Further, as described in a second example, when wafer bonding is conducted, a device to pressurize the wafer by a pneumatic piston once the wafer reaches the temperature at which the wafer is softened is necessary in order to suppress breakage or cracking of the wafer. This poses a problem of complicated manufacturing apparatuses and complicated control.

In the third background art, specific contents of the wafer bonding step are not provided.

Moreover, in the LED chips manufactured by the fourth background art, a groove having a width of 100 μm is formed on an epitaxial wafer at 300 μm intervals, and this causes a problem that a bonded face area between the epitaxial wafer and a GaP substrate is decreased.

### SUMMARY OF THE INVENTION

In consideration of the above situations, an object of the present invention is to provide a manufacturing method for semiconductor light emitting device allowing wafer bonding to be performed on the entire face of a wafer uniformly and easily with a high yield.

In order to accomplish the object, according to a first aspect of the present invention, there is provided a manufacturing method for a semiconductor light emitting device, including:

preparing a first wafer in which at least one semiconductor layer including the emitter layer is formed;

disposing a second wafer transparent to an emission wavelength of the emitter layer on the surface of the first wafer;

providing a bonding failure prevention structure to at least either the first wafer or the second wafer for preventing bonding failures of the first wafer and the second wafer; and

applying compressive force to a contact face between the first wafer and the second wafer while at the same time, heating the contact face.

According to the invention, the second wafer is disposed on the surface of the first wafer. At least either the first wafer or the second wafer has the bonding failure prevention structure. Under the presence of the bonding failure prevention structure, compressive force is applied to the contact face, while at the same time the contact face is heated. Therefore, in the case where the portions of the first wafer and the second wafer which come into contact with each other in the contact face are different from each other in, for example, coefficient of thermal expansion, it is still possible to prevent the bonding failures of the first and second wafers in the contact face.

According to a second aspect of the present invention, there is provided a manufacturing method for a semiconductor light emitting device, comprising:

preparing a first wafer in which at least one semiconductor layer including the emitter layer is formed;

disposing a second wafer, in which a transparent layer transparent to an emission wavelength of the emitter layer is formed, on a surface of the first wafer in a state that a surface of the transparent layer of the second wafer is in contact with the surface of the first wafer;

providing a bonding failure prevention structure to at least either the first wafer or the second wafer for preventing bonding failures of the first wafer and the second wafer; and

applying compressive force to a contact face between the first wafer and the second wafer while at the same time, heating the contact face.

According to the invention, the second wafer is disposed on the surface of the first wafer in the state that the surface of the transparent layer of the second wafer is in contact with the surface of the first wafer. At least either the first wafer or the second wafer is provided with the bonding failure prevention structure. Under the presence of the bonding failure prevention structure, compressive force is applied to the contact face while at the same time the contact face is heated. Therefore, in the case where the portions of the first wafer and the second wafer which come into contact with each other in the contact face are different from each other in, for example, coefficient of thermal expansion, it is still possible to prevent the bonding failures of the first and second wafers in the contact face.

In one embodiment, the bonding failure prevention structure is a stress relaxation film disposed on at least one face of the first wafer and the second wafer which is a face opposite to the contact face.

According to the embodiment, in the state that the stress relaxation film is disposed on at least one face of the first wafer and the second wafer which is the face opposite to the contact face, compressive force is applied to the contact face while at the same time the contact face is heated. This reduces bias in stress distribution on the contact face. Therefore, it becomes possible to prevent bonding failures of the first and second wafers in the contact face.

In one embodiment, the stress relaxation film has a stress relaxation rate of 1.5 to 3.0% in a range of a tightening surface pressure of 5 to 500 kg/cm².

According to the embodiment, with the stress relaxation film having a stress relaxation rate of 1.5 to 3.0% in the range of the tightening surface pressure of 5 to 500 kg/cm², bias of the stress on the bonded faces of the first and second wafers can be effectively reduced. More preferably, the stress relaxation film has a stress relaxation rate of 1.8 to 2.5% in the range of the tightening surface pressure of 5 to 20 kg/cm².

In one embodiment, the stress relaxation film has mm a thickness ranging from 0.2 mm to 2.0 mm.

According to the embodiment, the stress relaxation film having a thickness ranging from 0.2 mm to 2.0 mm makes it possible to effectively reduce the bias of the stress in the bonded faces of the first and second wafers.

In one embodiment, the bonding failure prevention structure is a groove placed at specified intervals in a state of facing the contact face.

According to the embodiment, under the presence of the groove placed at specified intervals in the state of facing the contact face, compressive force is applied to the contact face while at the same time the contact face is heated. This reduces bias in the stress distribution on the contact face. Therefore, it becomes possible to prevent bonding failures of the first and second wafers in the contact face. It is to be noted that the groove may be placed either on the first wafer or the second wafer.

In one embodiment, the groove is placed at intervals corresponding to a chip size of a semiconductor light emitting device.

According to the embodiment, the groove is placed at intervals corresponding to the chip size of semiconductor light emitting devices, and therefore by dividing the first and second wafers along the groove, semiconductor light emitting device chips can be easily obtained.

In one embodiment, the groove is formed by dicing.

According to the embodiment, the groove is formed by dicing, which makes it possible to provide the bonding failure prevention structure easily and to divide the first and second wafers into chips.

In one embodiment, the groove is formed by etching.

According to the embodiment, the groove is formed by etching, which makes it possible to provide the bonding failure prevention structure easily and to divide the first and second wafers into chips.

In one embodiment, the groove has a depth ranging from 5 μm to 80 μm.

According to the embodiment, the groove has a depth ranging from 5 μm to 80 μm, which makes it possible to effectively reduce bias in the stress distribution in the contact face. It is to be noted that in the first or second wafer where the groove is placed, the groove should preferably have a depth which makes the thickness from the bottom of the groove to the face opposed to the contact face 100 μm or more.

In one embodiment, the bonding failure prevention structure is at least one of the first wafer and the second wafer whose thickness is ranging from 100 μm to 300 μm.

According to the embodiment, at least one of the first wafer and the second wafer has a thickness ranging from 100 μm to 300 μm, so that when compressive force is applied to the contact face between the first and second wafers and at the same time heat is applied, bias in the stress distribution in the contact face is reduced. Therefore, it becomes possible to prevent bonding failures of the first and second wafers in the contact face.

In one embodiment, the bonding failure prevention structure is formed by at least one of grinding, etching and chemical polishing.

According to the embodiment, the bonding failure prevention structure can easily be obtained by at least one of grinding, etching and chemical polishing.

In one embodiment, at least one of the first wafer and the second wafer has a layer formed by MOCVD (Metal Organic Chemical Vapor Deposition) method or MBE (Molecular Beam Epitaxy) method.

According to the embodiment, at least one of the first wafer and the second wafer has a layer formed by MOCVD method or MBE method, and this layer needs a relatively long time to grow. Consequently, if the layer is once removed from the substrate as in the conventional examples, the layer needs to grow to have a relatively large thickness large enough to obtain a specified strength solely by the layer, and so the time necessary for the layer to grow becomes relatively long, which in returns makes a time necessary for manufacturing semiconductor light emitting devices relatively long. According to the above embodiment, however, the first and second wafers can be bonded in the state of the wafer without the necessity of removing the layer from the substrate, and therefore it is not necessary to grow the layer large enough to obtain the specified strength, which makes it possible to shorten the time necessary for manufacturing semiconductor light emitting devices. Further, the layer should be grown to have a minimum necessary thickness for light emission, which allows prevention of wasteful use of the material of the layer.

In one embodiment, the groove has a depth which is 1/20 to ⅓ of a thickness of the wafer on which the groove is formed.

According to the embodiment, it is possible to effectively reduce bias in the stress distribution in the contact face and to effectively prevent bonding failures of the first wafer and the second wafer. When the groove depth is larger than ⅓ of the wafer thickness, the wafer provided with the groove tends to crack. When the groove depth is smaller than 1/20 of the wafer thickness, the reduction effect of the bias in the stress distribution in the contact face becomes insufficient, thereby causing decrease in bonded areas of the first wafer and the second wafer.

In one embodiment, the groove has a width which is 1/20 to ⅕ of an interval at which the groove is placed.

According to the embodiment, it becomes possible to prevent stress distribution in the contact face from being biased for prevention of bonding failures while securing the contact areas of the first wafer and the second wafer. When the groove width is larger than ⅕ of the interval, the contact areas of the first wafer and the second wafer decrease. When the groove width is smaller than 1/20 of the interval, the reduction effect of the bias in the stress distribution in the contact face becomes insufficient, thereby causing decrease in bonded areas of the first wafer and the second wafer.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a view showing a bonding step in a manufacturing method for a semiconductor light emitting device in an embodiment of the present invention;

FIG. 2A is a view showing the state that a plurality of semiconductor layers including an emitter layer are formed on a substrate;

FIG. 2B is a view showing a first wafer;

FIG. 2C is a view showing the state that a second wafer is disposed on the surface of the first wafer;

FIG. 2D is a view showing the state that the substrate and a buffer layer are removed from the first wafer bonded to the second wafer;

FIG. 2E is a view showing the state that an etching stop layer on the first wafer side is etched away;

FIG. 2F is a view showing a finished product of a light emitting diode;

FIG. 3 is a view showing the state of the bonded first and second wafers as viewed from the side of the second wafer;

FIG. 4 is a view showing the surface of a first wafer in a manufacturing method for a semiconductor light emitting device in a second embodiment;

FIG. 5 is a view showing the state of the bonded first and second wafers as viewed from the side of the second wafer;

FIG. 6 is a view showing the surface and the lateral face of a first wafer in a manufacturing method for a semiconductor light emitting device in a third embodiment;

FIG. 7 is a front view showing the state of a bonding step in a conventional manufacturing method for a semiconductor light emitting device;

FIG. 8 is a plan view showing the state of a bonding step in a conventional manufacturing method for a semiconductor light emitting device;

FIG. 9 is a view showing a first wafer before being bonded in the conventional manufacturing method for a semiconductor light emitting device; and

FIG. 10 is a view showing first and second wafers after being bonded in the conventional manufacturing method for a semiconductor light emitting device.

### DETAILED DESCRIPTION OF THE INVENTION

Hereinbelow, the present invention will be described in detail in conjunction with embodiments with reference to the drawings.

In the embodiment, a light emitting diode as an AlGaInP (aluminum gallium indium phosphide)-based semiconductor light emitting device having a quarternary quantum well in an emitter layer is manufactured.

### First Embodiment

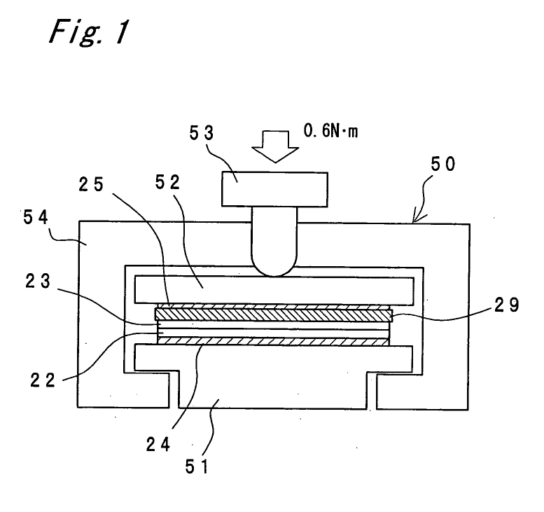

FIG. 1 is a view showing a bonding step in a manufacturing method for the light emitting diode. The bonding step is a step for bonding a first wafer 22 and a second wafer 23 by applying compressive force to a contact face between the first and second wafers 22 and 23 via a relaxation film 29 as a stress relaxation film constituting a bonding failure prevention structure and also by heating the contact face.

The first wafer 22 is a wafer having a plurality of semiconductor layers including an emitter layer formed on an n-type GaAs (gallium arsenide) substrate, and the second wafer 23 is a p-type GaP substrate 23 transparent to light from the emitter layer.

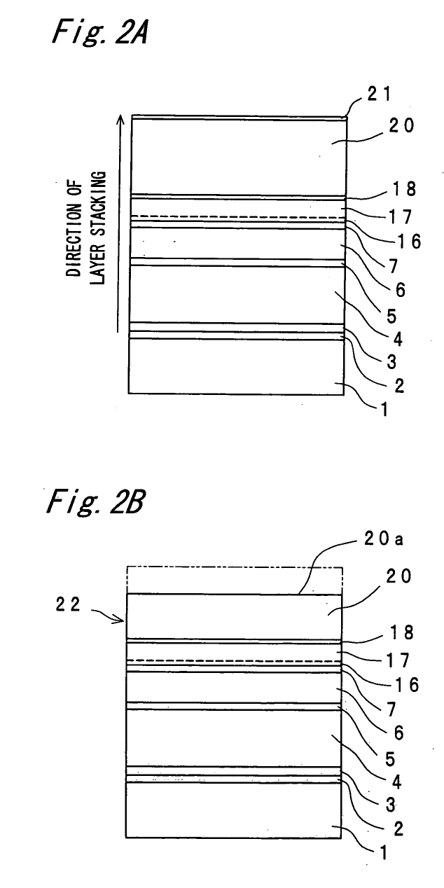

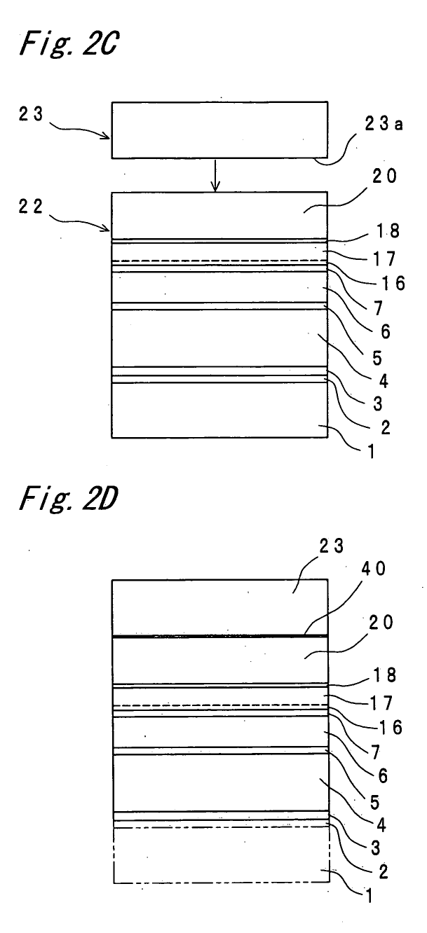

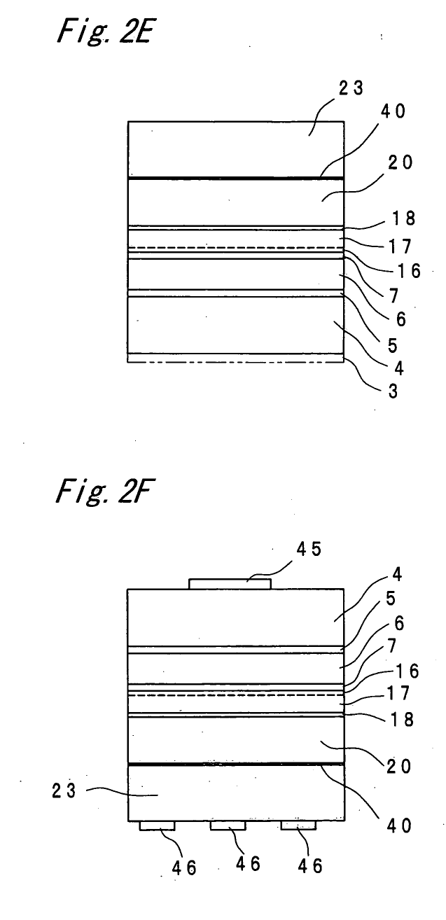

Hereinbelow, the manufacturing method for the light emitting diode will be described with reference to FIG. 2A to FIG. 2F. It is to be noted that FIG. 2A to FIG. 2E show the portions of the first wafer 22 and the second wafer 23 which should be divided into chips.

First, as shown in FIG. 2A, on a GaAs substrate 1, there are formed a buffer layer 2, an etching stop layer 3, a current diffusion layer 4, a buffer layer 5, a cladding layer 5, an emitter layer 7, a spacer layer 16, a cladding layer 17, an intermediate layer 18, an application contact layer 20 and a cap layer 21. The respective layers are grown by MOCVD method and have compositions and thicknesses as shown in Table 1 and Table 2.

TABLE 1

| Reference | | | |
|---|---|---|---|
| Number | Layer Name | Composition | Thickness |
| 1 | Substrate | GaAS | 350 μm |
| 2 | Buffer Layer | GaAs | 0.5 μm |
| 3 | Etching Stop Layer | Al_{0.7}Ga_{0.3}As | 0.2 μm |
| 4 | Current Diffusion | Al_{0.6}Ga_{0.4}As | 3 μm |
| | Layer | | |
| 5 | Buffer Layer | (Al_{0.7}Ga_{0.3})_{0.5}In_{0.5}P | 0.05 μm |
| 6 | Cladding Layer | Al_{0.5}In_{0.5}P | 1 μm |
| 7 | MQW Active Layer | (Al_{0.5}Ga_{0.5})_{0.5}In_{0.5}P | 0.1 μm |

TABLE 2

| | | | |
|---|---|---|---|
| 16 | Spacer Layer | Al_{0.5}In_{0.5}P | 0.15 μm |
| 17 | Cladding Layer | Al_{0.5}In_{0.5}P | 0.85 μm |
| 18 | Intermediate Layer | Al_{0.18}Ga_{0.62}In_{0.20}P | 0.12 μm |
| 20 | Application | GaP | 5 μm |
| | contact Layer | | |
| 21 | Cap Layer | GaAs | 0.01 μm |

Table 1 shows the compositions of the layers from the substrate 1 to the emitter layer 7. Table 2 shows the compositions of the layers from the spacer layer 16 on top of the emitter layer 7 to the cap layer 21. As shown in Table 1, though not shown in the drawing, the emitter layer 7 is composed of a quarternary quantum well layer formed by alternate lamination of well layers and barrier layers.

Moreover, in the GaAs substrate 1, the orientation of the surface on which the respective layers are grown is 15° off the (100) orientation toward <011> direction. The surface of the GaAs substrate 1 may take other orientations.

Moreover, each layer on the GaAs substrate 1 may be formed by MBE method.

Next, as shown in FIG. 2B, the cap layer 21 is removed, and a portion corresponding to a thickness of about 2 μm is removed from the application contact layer 20 exposed by the removal of the cap layer 21. Then, the surface of the application contact layer 20 devoid of the portion is polished by CMP (Chemical Mechanical Polishing) method to a mirror-smooth state. Thus, the first wafer 22 is prepared.

Then, as shown in FIG. 2C, a GaP substrate 23 that is the second wafer is disposed on the surface of the application contact layer 20 that is the surface of the first wafer 22 so as to be aligned with the crystallographic axis of the GaAs substrate 1 of the first wafer. Then a bonding step of the first wafer 22 and the second wafer 23 is performed.

In this bonding step, with use of a jig 50 as shown in FIG. 1, the first wafer 22 and the second wafer 23 are bonded. The jig 50, which is made from quartz, has a lower base 51 for supporting the first wafer 22, a retainer plate 52 for covering the upper-side face of the second wafer 23 in FIG. 1, and a pressing portion 53 for pressing the retainer plate 52 upon reception of force with a specified strength. The pressing portion 53 is guided in vertical direction by a frame article 54 having an almost letter C shape as viewed from the front The frame article 54 engages with the lower base 51 and properly transmits force to the retainer plate 52 positioned in between the lower base 51 and the pressing portion 53.

A first PBN (Pyrolytic Boron Nitride) film 24 is disposed. on the lower base 51 of the jig, and the first wafer 22 and the second wafer 23 are disposed on the first PBN film 24. In this case, the surface of the second wafer 23 is also polished to a mirror-smooth state, and this mirror polished surface is disposed so as to be in contact with the mirror polished surface of the first wafer 22. Moreover, a growth axis on the surface of the first wafer 22 and a growth axis on the surface of the second wafer 23 are aligned. A relaxation film 29 as the bonding failure prevention structure is disposed on the upper-side face of the second wafer 23, which is the face opposed to the contact face between the first and second wafers 22 and 23.

The relaxation film 29 is formed from a material having a stress relaxation rate of 1.5 to 3.0% in the range of the tightening surface pressure of 5 to 500 kg/cm², and is 1 mm in thickness. The relaxation film 29 is formed by carbon. The relaxation film 29 may be formed by material including SiO₂ or Al₂O₃, for example, ceramic fiber or glass wool mat.

A second PBN film 25 is disposed on the upper-side face of relaxation film 29, and the retainer plate 52 of the jig is brought into contact with the upper-side face of the second PBN film 25. Then, force of 0.6 Nm is applied to the pressing portion 53 of the jig so that compressive force is applied to the contact face between the second wafer 23 and the first wafer 22 via the retainer plate 52 and the relaxation film 29. In this state, the first and second wafers 22 and 23 are put in a heating furnace together with the jig 50, and is heated at a temperature of 750° C. for 1 hour. Herein, the compressive force is applied to the contact face between the first and second wafers 22 and 23 in the state that bias of the stress is reduced by the relaxation film 29. This forms a sufficient bonding interface 40 across almost the entire surface of the contact face.

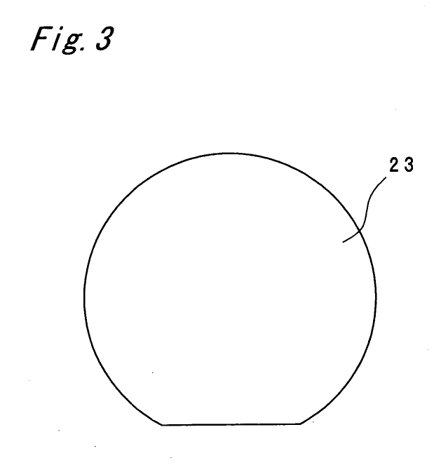

After heating is ended and cooling is performed, the bonded first and second wafers 22 and 23 are taken out of the heating furnace. An assembly of the first and second wafers 22 and 23 obtained by such wafer bonding (direct bonding) is free from cracks, bonding failures or the like as shown in the plane view in FIG. 3.

Then, as shown in FIG. 2D, the substrate 2 and the buffer layer 2 on the first wafer side are etched away with NH₄OH—H₂O₂ mixed solution.

Next, as shown in FIG. 2E, the etching stop layer 3 on the first wafer side is etched away. Then, an N (negative) electrode 45 is formed on the surface of the current diffusion layer 4 exposed by the removal of the etching stop layer 3. The GaP substrate 23 on the second wafer side is formed to have a specified thickness by backgriding of its surface portion, and a P (positive) electrode 46 is formed on the grinded surface. Next, for allying a junction portion between the wafers and the electrodes 45, 46, heat treatment is performed at a temperature of about 450° C. for 15 minutes. Then, the first and second wafers 22 and 23 with the electrodes 45, 46 formed thereon are divided into chips by dicing, by which light emitting diodes as shown in FIG. 2F are completed.

The thus-manufactured light emitting diode had sufficient bonding between the GaP substrate 23 and the application contact layer 20. Moreover, in the manufacturing process, failures such as peel-off in the bonding portion were not caused after the removal of the substrate 1, the buffer layer 2 and the etching stop layer 3 by etching after bonding nor after dicing involving application of relatively large force.

Thus, according to the manufacturing method for a semiconductor light emitting device in the present embodiment, the first and second wafers 22 and 23 can be bonded uniformly across their entire surfaces by a relatively easy method. This makes it possible to manufacture light emitting diodes with relatively high emission intensity with a yield better than before.

According to the embodiment, the relaxation film 29 has a stress relaxation rate of 1.5 to 3.0% in the range of a tightening surface pressure of 5 to 500 kg/cm². However, the relaxation film 29 needs only to have a stress relaxation rate of 1.5 to 5.0% in the range of a tightening surface pressure of 5 to 500 kg/cm². More preferably, the stress relaxation rate should be 1.8 to 2.5% in the range of a tightening surface pressure of 5 to 20 kg/cm².

Moreover, without being limited to 1 mm, the thickness of the relaxation film 29 may appropriately be set in the range from 0.2 mm to 2.0 mm.

Moreover, the relaxation film 29 may be disposed on the lower-side face of the first wafer 22 instead of the upper-side face of the second wafer 23.

### Second Embodiment

A manufacturing method for a semiconductor light emitting device in the present embodiment is similar to that in the first embodiment except that the bonding failure prevention structure is a groove formed on the surface of the first wafer 22. In the present embodiment, component members identical to those in the first embodiment are designated by identical reference numerals, and detailed description thereof will be omitted.

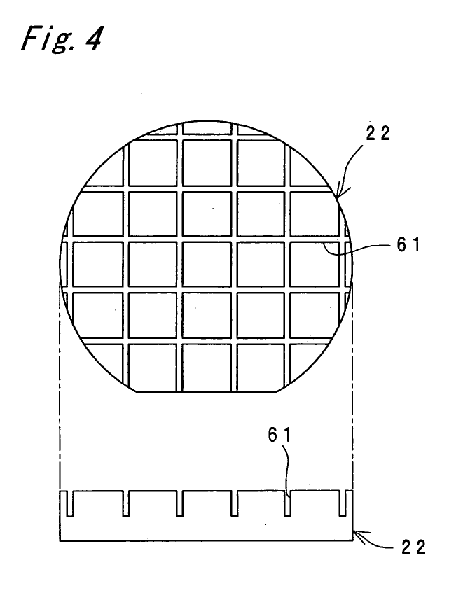

In the present embodiment, after the first wafer 22 shown in FIG. 2B is formed, grooves 61 extending from the surface of the application contact layer 20 to a specified depth are formed in lengthwise and widthwise direction on the surface of the first wafer 22 as shown in FIG. 4. The groove 61, which functions as the bonding failure prevention structure, is formed by dicing. The groove 61 should preferably have a depth of 1/20 to ⅓ of the thickness of the first wafer 22. More preferably, the groove 61 should have a depth of 5 to 80 μm. Moreover, the intervals of lengthwise grooves 61 are formed as equal as the length of the LED to be produced, while the intervals of widthwise grooves 61 are formed as equal as the width of the LED to be produced.

Then, the first wafer 22 with the grooves 61 formed thereon is disposed on the lower base 51 of the jig through the first PBN film 24 as with the case in FIG. 1 with the surface having the grooves 61 formed thereon facing up. A GaP substrate 23 that is the second wafer is disposed on the first wafer 22 in such a way that the mirror polished surface of the GaP substrate 23 is in contact with the groove-formed surface of the first wafer 22. Herein, a growth axis on the surface of the first wafer 22 and a growth axis on the surface of the second wafer 23 are aligned.

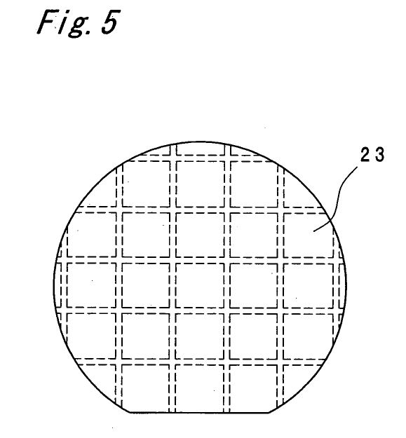

Next, the second PBN film 25 is disposed on the upper side of the second wafer 23, and the retainer plate 52 is disposed so that compressive force is applied to the contact face between the first and second wafers 22 and 23 via the pressing portion 53. In this state, the wafers are heated in a heating furnace at a temperature of 750° C. for 1 hour and then are cooled, by which a wafer assembly free from cracks and bonding failures as shown in FIG. 5 is obtained.

According to the present embodiment, the grooves 61 in lengthwise and widthwise directions are formed on the bonded face of the first wafer 22, and therefore by setting the formation intervals of the grooves 61 in compliance with chip sizes, an assembly of the first and second wafers 22 and 23 can be divided into chips along the grooves 61 relatively easily.

It is to be noted that the formation method of the grooves 61 is not limited to dicing, and so the grooves 61 may be formed by etching.

Moreover, the groove facing the bonded face may be provided not on the surface of the first wafer 22 but on the surface of the second wafer 23.

Moreover, the grooves 61 should preferably have a width ranging from 1/20 to ⅕ times the interval at which the grooves 61 are provided. More specifically the grooves 61 should preferably be formed to have a width ranging from 10 μm to 50 μm.

Moreover, in the present embodiment, the bonding failure prevention structure in the first embodiment may also be used. More particularly, at least one groove 61 may be provided on the contact face of the first wafer 22 or the second wafer 23, in addition to which a relaxation film similar to the relaxation film 29 in the first embodiment may be disposed on the face opposite to the contact face between the first wafer 22 and the second wafer 23 so that compressive force is applied to the contact face between the first wafer 22 and the second wafer 23 through the relaxation film. The synergistic effects of the groove 61 and the relaxation film 29 allow effective reduction of bias in stress distribution in the contact face and allow effective prevention of cracks and bonding failures of the first and second wafers 22 and 23.

### Third Embodiment

A manufacturing method for a semiconductor light emitting device in the present embodiment is similar to that in the first embodiment except that the bonding failure prevention structure is a first wafer 22 formed to have a specified thickness. In the present embodiment, component members identical to those in the first embodiment are designated by identical reference numerals, and detailed description thereof will be omitted.

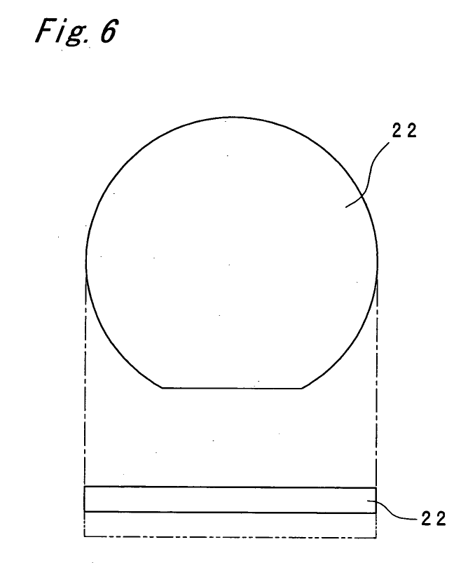

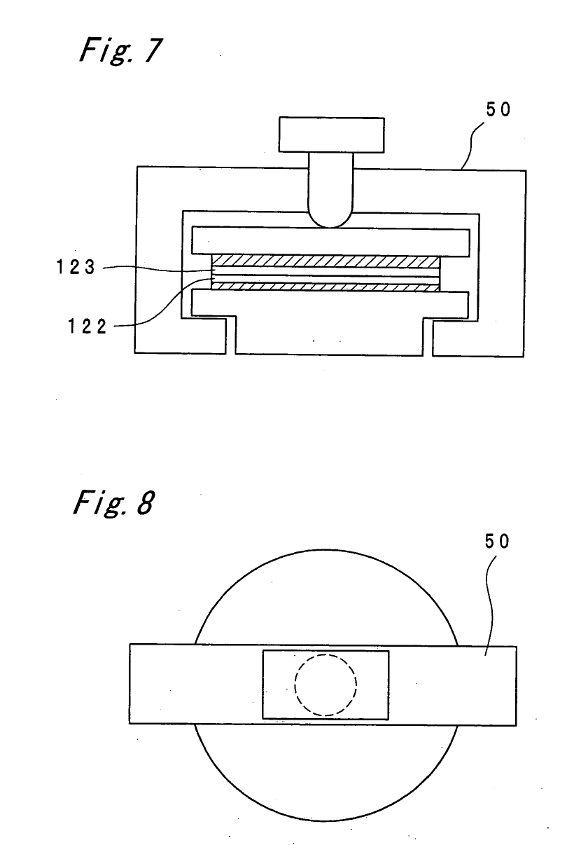

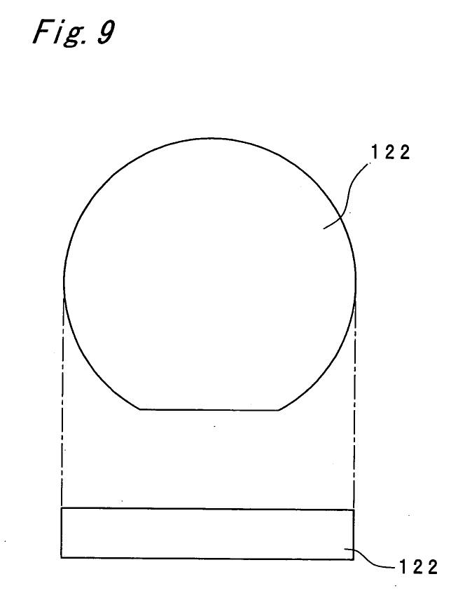

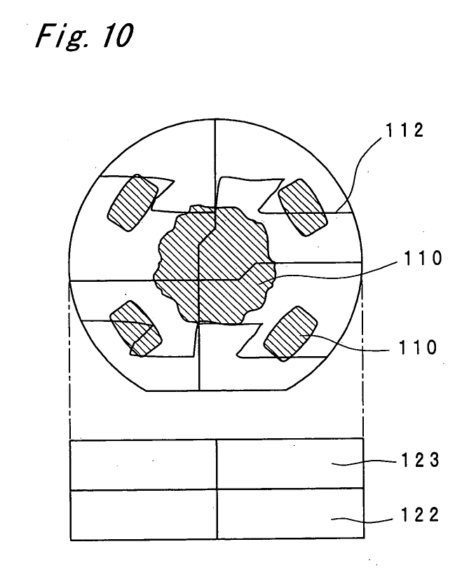

In the present embodiment, after the first wafer 22 shown in FIG. 2B is formed, a surface portion of the first wafer 22 on the GaAs substrate 1 side is grinded by a back grinder as shown in FIG. 6. By this grinding, the thickness of the GaAs substrate 1 of the first wafer 22 is changed from about 350 μm to 250 μm. Consequently, the total thickness of the first wafer 22 becomes about 256 μm. The first wafer 22 formed to have this thickness functions as the bonding failure prevention structure.

Then, the first wafer 22 having the GaAs substrate 1 with a reduced thickness is disposed on the lower base 51 of the jig through the first PBN film 24 as with the case in FIG. 1 with the surface of the application contact layer 20 facing up. A GaP substrate 23 that is the second wafer is disposed on the first wafer 22 in such a way that the mirror polished surface of the GaP substrate 23 is in contact with the surface of the application contact layer 20 of the first wafer 22. Herein, a growth axis on the surface of the first wafer 22 and a growth axis on the surface of the second wafer 23 are aligned.

Next, the second PBN film 25 is disposed on the upper side of the second wafer 23, and the retainer plate 52 is disposed so that compressive force is applied to the contact face between the first and second wafers 22 and 23 via the pressing portion 53. In this state, the wafers are heated in a heating furnace at a temperature of 750° C. for 1 hour and then are cooled, by which a wafer assembly free from cracks and bonding failures is obtained.

According to the present embodiment, the thickness of the first wafer 22 is reduced to be in the range from 100 μm to 300 μm, which prevents bias of stress from being generated in the contact face between the first and second wafers 22 and 23 during bonding. This makes it possible to provide a wafer assembly free from cracks and bonding failures.

It is to be noted that the thickness of the first wafer 22 may be reduced by polishing methods other than the back grinding, and may also be reduced by etching and chemical polishing.

Further, instead of the first wafer 22, the second wafer 23 may be formed to have a specified thickness, and the second wafer 23 formed to have this thickness may function as the bonding failure prevention structure.

Moreover, although in each of the embodiments, the light emitting diode as a semiconductor light emitting device has an AlGaInP quarternary-based emitter layer, the structure of the emitter layer is not limited to the quantum well structure, and the present invention may widely be applied to light emitting diodes of other compositions. More particularly, without being limited to the compositions and luminescent colors such as red (AlGaAs etc.), blue (GaN, InGaN, SiC, etc.), yellow (AlGaInP etc.) and green (AlGaInP etc.), the present invention is applicable to any light emitting diodes.

Moreover, although as the second wafer, the GaP substrate transparent to light from the emitter layer 7 of the first wafer, substrates made of other materials may be used. Moreover, the second wafer may be structured by forming a transparent layer transparent to light from the emitter layer 7 on a substrate opaque to the light, and in this case, the transparent layer should be bonded to the surface of the first wafer.

Moreover, the present invention is applicable to semiconductor lasers and the like in addition to the light emitting diodes.

Further, two or more bonding failure prevention structures stated in the first to third embodiments may be used redundantly, which allows the first wafer 22 and the second wafer 23 to be bonded more effectively in the state free from cracks and bonding failures.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A manufacturing method for a semiconductor light device, comprising:
preparing a first wafer in which at least one semiconductor layer including the emitter layer is formed;
disposing a second wafer transparent to an emission wavelength of the emitter layer on the surface of the first wafer;
providing a bonding failure prevention structure to at least either the first wafer or the second wafer for preventing bonding failures of the first wafer and the second wafer; and
applying compressive force to a contact face between the first wafer and the second wafer while at the same time, heating the contact face.

2. A manufacturing method for a semiconductor light emitting device, comprising:
preparing a first wafer in which at least one semiconductor layer including the emitter layer is formed;
disposing a second wafer, in which a transparent layer transparent to an emission wavelength of the emitter layer is formed, on a surface of the first wafer in a state that a surface of the transparent layer of the second wafer is in contact with the surface of the first wafer;
providing a bonding failure prevention structure to at least either the first wafer or the second wafer for preventing bonding failures of the first wafer and the second wafer; and
applying compressive force to a contact face between the first wafer and the second wafer while at the same time, heating the contact face.

3. The manufacturing method for a semiconductor light emitting device as defined in claim 1, wherein
the bonding failure prevention structure is a stress relaxation film disposed on at least one face of the first wafer and the second wafer which is a face opposite to the contact face.

4. The manufacturing method for a semiconductor light emitting device as defined in claim 3, wherein
the stress relaxation film has a stress relaxation rate of 1.5 to 3.0% in a range of a tightening surface pressure of 5 to 500 kg/cm².

5. The manufacturing method for a semiconductor light emitting device as defined in claim 3, wherein
the stress relaxation film has a thickness ranging from 0.2 mm to 2.0 mm.

6. The manufacturing method for a semiconductor light emitting device as defined in claim 1, wherein
the bonding failure prevention structure is a groove placed at specified intervals in a state of facing the contact face.

7. The manufacturing method for a semiconductor light emitting device as defined in claim 6, wherein
the groove is placed at intervals corresponding to a chip size of a semiconductor light emitting device.

8. The manufacturing method for a semiconductor light emitting device as defined in claim 6, wherein
the groove is formed by dicing.

9. The manufacturing method for a semiconductor light emitting device as defined in claim 6, wherein
the groove is formed by etching.

10. The manufacturing method for a semiconductor light emitting device as defined in claim 6, wherein
the groove has a depth ranging from 5 μm to 80 μm.

11. The manufacturing method for a semiconductor light emitting device as defined in claim 1, wherein
the bonding failure prevention structure is at least one of the first wafer and the second wafer whose thickness is ranging from 100 μm to 300 μm.

12. The manufacturing method for a semiconductor light emitting device as defined in claim 11, wherein
the bonding failure prevention structure is formed by at least one of grinding, etching and chemical polishing.

13. The manufacturing method for a semiconductor light emitting device as defined in claim 1, wherein
at least one of the first wafer and the second wafer has a layer formed by MOCVD method or MBE method.

14. The manufacturing method for a semiconductor light emitting device as defined in claim 6, wherein
the groove has a depth which is 1/20 to ⅓ of a thickness of the wafer on which the groove is formed.

15. The manufacturing method for a semiconductor light emitting device as defined in claim 6, wherein
the groove has a width which is 1/20 to ⅕ of an interval at which the groove is placed.

16. The manufacturing method for a semiconductor light emitting device as defined in claim 2, wherein
the bonding failure prevention structure is a stress relaxation film disposed on at least one face of the first wafer and the second wafer which is a face opposite to the contact face.

17. The manufacturing method for a semiconductor light emitting device as defined in claim 4, wherein
the stress relaxation film has a thickness ranging from 0.2 mm to 2.0 mm.

18. The manufacturing method for a semiconductor light emitting device as defined in claim 2, wherein
the bonding failure prevention structure is a groove placed at specified intervals in a state of facing the contact face.

19. The manufacturing method for a semiconductor light emitting device as defined in claim 2, wherein
the bonding failure prevention structure is at least one of the first wafer and the second wafer whose thickness is ranging from 100 μm to 300 μm.
